(19) United States
(12) Patent Application Publication
(10) Pub. No.: US 2025/0391683 A1
(43) Pub. Date: Dec. 25, 2025

(54) SUBSTRATE TREATMENT DEVICE AND FILM THICKNESS ESTIMATION METHOD

(71) Applicant: Tokyo Electron Limited, Minato-ku, Tokyo (JP)

(72) Inventor: Hiroshi MARUMOTO, Koshi City, Kumamoto (JP)

(21) Appl. No.: 18/880,380

(22) PCT Filed: Jun. 28, 2023
(86) PCT No.: PCT/JP2023/023980

§ 371 Date: Dec. 31, 2024

(30) Foreign Application Priority Data
Jul. 12, 2022 (JP) 2022-111975

(51) Int. Cl. H01L 21/67; H01L 21/311; H01L 21/3213; H01L 21/66

(52) U.S. Cl. CPC H01L 21/67253; H01L 21/6708; H01L 22/12; H01L 21/31111; H01L 21/32134

(57) ABSTRACT

A substrate processing apparatus includes: a holder configured to hold a substrate having a film formed on a surface; a supply configured to supply an etching liquid to the surface; an optical sensor configured to irradiate an irradiation position with light and receive reflected light of the irradiated light; and a controller. The controller is configured to execute: a first process of supplying the etching liquid to the surface of the substrate; a second process of acquiring a change in intensity of the reflected light from the irradiation position, received by the optical sensor, while the etching liquid is being supplied; a third process of generating correction data by removing a disturbance component generated by an influence of a disturbance inducer located above the substrate from intensity change data; and a fourth process of estimating a thickness of the film during an etching process based on the correction data.

### TECHNICAL FIELD

The present disclosure relates to a substrate processing apparatus and a film thickness estimation method.

### BACKGROUND

Currently, when manufacturing a semiconductor device by micro-processing a substrate (e.g., a semiconductor wafer), a substrate processing system that performs substrate processing by discharging various processing liquids onto the substrate has been known. Patent Document 1 discloses a film thickness measurement method including a process of guiding light from a light source (a halogen lamp) to the surface of the substrate via a lens, a mirror, etc., a process of receiving light reflected from the surface of the substrate by a light receiving means, and a process of collectively calculating the film thickness of a thin film formed on the surface of the substrate based on information representing a two-dimensional spatial distribution of the amount of the reflected light.

### PRIOR ART DOCUMENTS

### Patent Documents

Patent Document 1: Japanese Patent Laid-Open Publication No. H10-047926

The present disclosure describes a substrate processing apparatus and a film thickness estimation method capable of estimating, with high precision, film thickness that changes over time during an etching process even in an environment with disturbance.

### SUMMARY

An example of a substrate processing apparatus includes: a holder configured to hold a substrate having a film formed on a surface thereof; a supply configured to supply an etching liquid to the surface of the substrate; an optical sensor configured to irradiate an irradiation position set to overlap the surface of the substrate held by the holder with light of a predetermined wavelength and receive reflected light of the irradiated light; and a controller. The controller is configured to execute: a first process of supplying the etching liquid to the surface of the substrate held by the holder by controlling the supply; a second process of acquiring a change in intensity of the reflected light from the irradiation position, received by the optical sensor, while the etching liquid is being supplied to the surface of the substrate; a third process of generating correction data by removing a disturbance component generated by an influence of a disturbance inducer located above the substrate from intensity change data representing the change in the intensity of the reflected light acquired in the second process; and a fourth process of estimating a thickness of the film during an etching process based on the correction data.

According to a substrate processing apparatus and a film thickness estimation method of the present disclosure, it is possible to estimate, with high precision, film thickness that changes over time during an etching process even in an environment with disturbance.

### BRIEF DESCRIPTION OF DRAWINGS

FIG. 1 is a plan view schematically illustrating an example of a substrate processing system.

FIG. 2 is a side view schematically illustrating an example of a liquid processing unit.

FIGS. 3A and 3B are top views illustrating an example of irradiation positions by light sensors.

FIG. 4 is a block diagram illustrating an example of main portions of a substrate processing system.

FIGS. 5A to 5C are diagrams illustrating an example of models representing the relationship between film thickness and reflection intensity.

FIGS. 6A to 6C are diagrams illustrating an example of a model representing the relationship between film thickness and reflection intensity.

FIGS. 7A to 7C are diagrams illustrating an example of models representing the relationship between film thickness and reflection intensity.

FIG. 8 is a schematic diagram illustrating an example of a hardware configuration of a controller.

FIG. 9 is a flowchart for explaining an example of a substrate processing order.

FIG. 10 is a graph illustrating an example of intensity change data at a predetermined irradiation position.

FIG. 11 is a graph illustrating an example of correction data.

FIG. 12 is a side view schematically illustrating another example of the liquid processing unit.

FIGS. 13A to 13C are diagrams illustrating another example of the models representing the relationship between film thickness and reflection intensity.

### DETAILED DESCRIPTION

In the following description, the same symbol is used for the same elements or elements having the same function, and redundant descriptions are omitted. In addition, in this specification, reference to the upper side, lower side, right side, and left side of a drawing is based on the direction of a symbol in the drawing.

### Configuration of Substrate Processing System

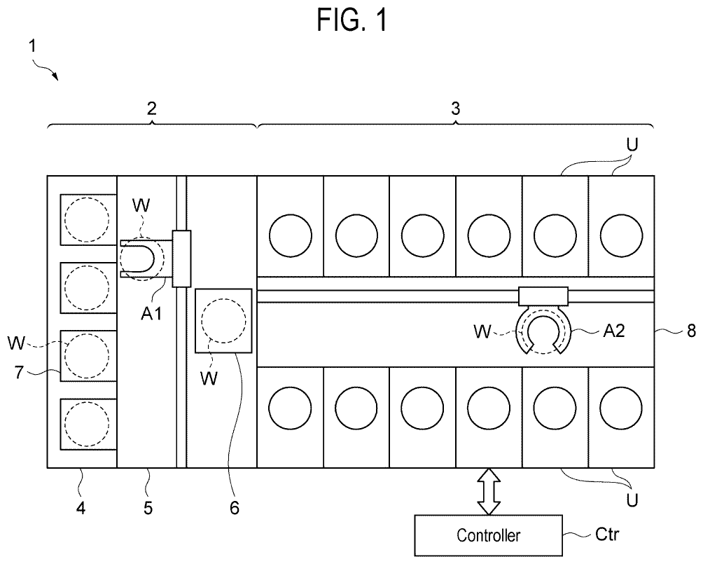

First, a substrate processing system 1 (substrate processing apparatus) configured to process a substrate W will now be described with reference to FIG. 1. The substrate processing system 1 includes a loading/unloading station 2, a processing station 3, and a controller Ctr. The loading/unloading station 2 and the processing station 3 may be arranged, for example, in a row in a horizontal direction.

The substrate W may have a disk shape or may have a plate shape such as a polygon other than a circle. The substrate W may have a cutout portion in which a part of the substrate is cut out. The cutout portion may be, for example, a notch (such as a U-shaped or a V-shaped groove) or a linear portion (so-called an orientation flat) extending in a straight line. The substrate W may be, for example, a semiconductor substrate (silicon wafer), a glass substrate, a mask substrate, a flat panel display (FPD) substrate, or any other type of substrate. The diameter of the substrate W may be, for example, about 200 mm to 450 mm.

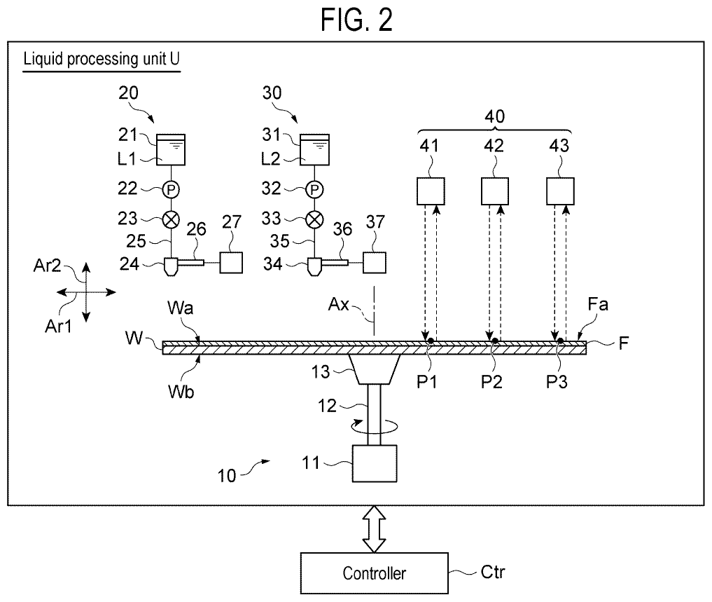

As illustrated in FIG. 2, a film F is formed on an upper surface Wa of the substrate W. The film F may be a thermal oxide (Th-Ox) film or a metal film. The metal film may be, for example, titanium nitride, silicon nitride (SiN), titanium oxide, titanium, tungsten, tantalum, tantalum nitride, aluminum, aluminum oxide, copper, ruthenium, zirconium oxide, hafnium oxide, or the like. In this specification, the “surface of the substrate W” refers to the outermost surface of the substrate W. That is, in the example of FIG. 2 in which the film F is formed on the upper surface Wa of the substrate W, the “surface of the substrate W” refers to an upper surface Fa of the film F.

The loading/unloading station 2 includes a stage portion 4 (acquirer), a loading/unloading portion 5, and a shelf unit 6. The stage portion 4 includes a plurality of stages (not shown) arranged in a width direction (vertical direction in FIG. 1). Each stage is configured so as to mount a carrier 7. The carrier 7 is configured to hermetically accommodate at least one substrate W. The carrier 7 includes an opening/closing door (not shown) for introducing the substrate W.

The loading/unloading portion 5 is disposed adjacent to the stage portion 4 in a direction in which the loading/unloading station 2 and the processing station 3 are arranged (left and right direction in FIG. 1). The loading/unloading portion 5 includes an opening/closing door (not shown) provided for the stage portion 4. When the carrier 7 is placed on the stage portion 4, both the opening/closing door of the carrier 7 and the opening/closing door of the loading/unloading portion 5 are opened, so that the loading/unloading portion 5 and the carrier 7 communicate with each other.

The loading/unloading portion 5 incorporates a transfer arm A1 and the shelf unit 6. The transfer arm A1 is configured to be capable of performing horizontal movement in a width direction of the loading/unloading portion 5, up and down movement in a vertical direction, and rotational operation around a vertical axis. The transfer arm A1 is configured to take the substrate W out of the carrier 7 and pass the substrate W to the shelf unit 6. In addition, the transfer arm A1 is configured to receive the substrate W from the shelf unit 6 and return the substrate W to the carrier 7. The shelf unit 6 is located near the processing station 3 and is configured to accommodate the substrate W.

The processing station 3 includes a transfer portion 8 and a plurality of liquid processing units U (substrate processing apparatuses). The transfer portion 8 extends horizontally, for example, in a direction in which the loading/unloading station 2 and the processing station 3 are arranged (left and right direction in FIG. 1). The transfer portion 8 incorporates a transfer arm A2 (transfer portion). The transfer arm A2 is configured to be capable of performing horizontal movement in a longitudinal direction of the transfer portion 8, up and down movement in a vertical direction, and rotational operation around a vertical axis. The transfer arm A2 is configured to take the substrate W out of the shelf unit 6 and pass the substrate to the liquid processing units U. In addition, the transfer arm A2 is configured to receive the substrate W from the liquid processing units U and return the substrate W to the shelf unit 6.

The plurality of liquid processing units U is arranged in a row on both sides of the transfer portion 8 in a longitudinal direction of the transfer portion 8 (left and right direction in FIG. 1). The liquid processing units U are configured to perform predetermined processes (e.g., an etching process, a cleaning process, etc.) on the substrate W. Details of the liquid processing units U will be described later.

The controller Ctr is configured to control the substrate processing system 1 partially or entirely. Details of the controller Ctr will be described later.

### Details of Liquid Processing Unit

Next, the liquid processing unit U will be described in detail with reference to FIGS. 2 to 4. As illustrated in FIG. 2, the liquid processing unit U includes a rotation holder 10 (holder), supplies 20 and 30, and a plurality of optical sensors 40.

The rotation holder 10 includes a driver 11, a shaft 12, and a holder 13. The driver 11 is configured to operate based on an operation signal from the controller Ctr and rotate the shaft 12. The driver 11 may be, for example, a power source such as an electric motor.

The holder 13 is provided at a tip end portion of the shaft 12. The holder 13 is configured to adsorb and hold a lower surface Wb of the substrate W, for example, by adsorption, etc. That is, the rotation holder 10 may be configured to rotate the substrate W around a rotational center axis Ax which is perpendicular to the surface of the substrate W in a state in which the substrate W is in a substantially horizontal position.

The supply 20 is configured to supply an etching liquid L1 to the surface of the substrate W. The etching liquid L1 may be, for example, an acid-based chemical liquid, an alkaline-based chemical liquid, or an organic chemical liquid. The acid-based chemical liquid may include, for example, SC-2 liquid (a mixture of hydrochloric acid, hydrogen peroxide, and pure water), SPM (a mixture of sulfuric acid and hydrogen peroxide), HF liquid (hydrofluoric acid), DHF liquid (dilute hydrofluoric acid), HNO₃+HF liquid (a mixture of nitric acid and hydrofluoric acid), etc. The alkaline-based chemical liquid may include, for example, SC-1 liquid (a mixture of ammonia, hydrogen peroxide, and pure water), hydrogen peroxide, etc.

The supply 20 includes a liquid source 21, a pump 22, a valve 23, a nozzle 24 (a disturbance inducer), a pipe 25, an arm 26 (a disturbance inducer), and a drive source 27. The liquid source 21 is a supply source of the etching liquid L1. The pump 22 is configured to operate based on an operation signal from the controller Ctr and send the etching liquid L1 sucked from the liquid source 21 to the nozzle 24 via the pipe 25 and the valve 23.

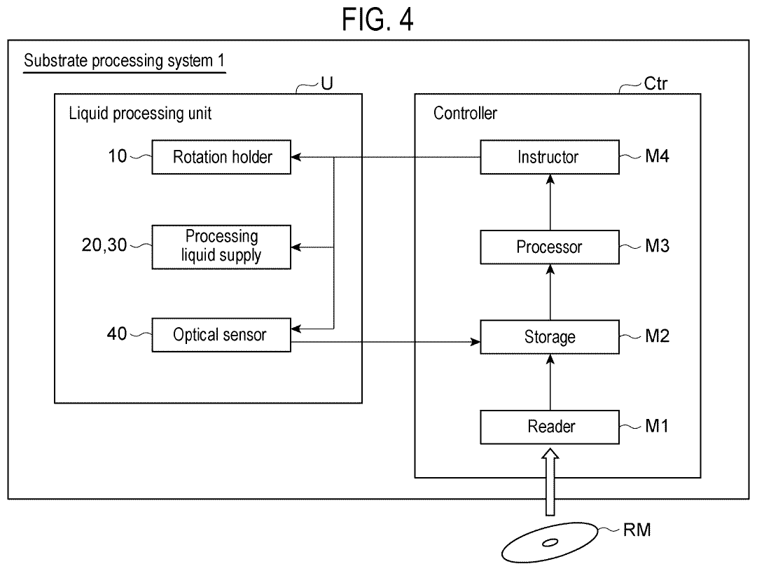

The valve 23 is configured to operate based on an operation signal from the controller Ctr and transition between an open state that allows the flow of a fluid in the pipe 25 and a closed state that prevents the flow of the fluid in the pipe 25. The nozzle 24 is disposed above the substrate W so that a discharge port of the nozzle 24 faces the surface of the substrate W. The nozzle 24 is configured to discharge the etching liquid L1 sent from the pump 22 toward the surface of the substrate W from the discharge port. Since the substrate W rotates by the rotation holder 10, the etching liquid L1 discharged onto the surface of the substrate W expands from a central portion of the substrate W toward a peripheral portion of the substrate W at a predetermined diffusion speed and is shaken off from the periphery of the substrate W to the outside (see FIG. 4).

The pipe 25 connects the liquid source 21, the pump 22, the valve 23, and the nozzle 24 in this order from an upstream side. The arm 26 holds the nozzle 24. The drive source 27 is connected to the arm 26. The drive source 27 is configured to operate based on an operation signal from the controller Ctr and move the arm 26 in a horizontal or vertical direction above the substrate W (see arrows Ar1 and Ar2 in FIG. 2). Therefore, the etching liquid L1 can be discharged not only toward the center of the surface of the substrate W, but also toward any position on the surface of the substrate W. For example, while the nozzle 24 continues to discharge the etching liquid L1, the nozzle 24 may move from the periphery of the substrate W toward the central portion of the substrate W (so-called scan-in operation). Alternatively, while the nozzle 24 continues to discharge the etching liquid L1, the nozzle 24 may move from the central portion of the substrate W toward the periphery of the substrate W (so-called scan-out operation).

The supply 30 is configured to supply a rinse liquid L2 to the substrate W. The rinse liquid L2 is a liquid for removing (rinsing away), from the substrate W, the etching liquid L1 supplied to the surface of the substrate W, a dissolved component of the film F by the etching liquid L1, an etching residue, and the like. The rinse liquid L2 may include, for example, deionized water (DIW), ozone water, carbonated water (CO2 water), ammonia water, and the like.

The supply 30 includes a liquid source 31, a pump 32, a valve 33, a nozzle 34, a pipe 35, an arm 36, and a drive source 37. The liquid source 31 is a supply source of the rinse liquid L2. The pump 32 is configured to operate based on an operation signal from the controller Ctr and send the rinse liquid L2 sucked from the liquid source 31 to the nozzle 34 via the pipe 35 and the valve 33.

The valve 33 is configured to operate based on an operation signal from the controller Ctr and transition between an open state that allows the flow of a fluid in the pipe 35 and a closed state that prevents the flow of the fluid in the pipe 35. The nozzle 34 is disposed above the substrate W so that a discharge port faces the surface of the substrate W. The nozzle 34 is configured to discharge the rinse liquid L2 sent from the pump 32 toward the surface of the substrate W from the discharge port. Since the substrate W rotates by the rotation holder 10, the rinse liquid L2 discharged onto the surface of the substrate W expands from a central portion of the substrate W toward a peripheral portion of the substrate W at a predetermined diffusion speed and is shaken off from the periphery of the substrate W to the outside.

The pipe 35 connects the liquid source 31, the pump 32, the valve 33, and the nozzle 34 in this order from an upstream side. The arm 36 holds the nozzle 34. The drive source 37 is connected to the arm 36. The drive source 37 is configured to operate based on an operation signal from the controller Ctr and move the arm 36 in a horizontal or vertical direction above the substrate W (see arrows Ar1 and Ar2 in FIG. 2). Therefore, the rinse liquid L2 can be discharged not only toward the central portion of the surface of the substrate W, but also toward any position on the surface of the substrate W. For example, while the nozzle 34 continues to discharge the rinse liquid L2, the nozzle 34 may move from the periphery of the substrate W toward the central portion of the substrate W (so-called scan-in operation). Alternatively, while the nozzle 34 continues to discharge the rinse liquid L2, the nozzle 34 may move from the central portion of the substrate W toward the periphery of the substrate W (so-called scan-out operation).

The plurality of optical sensors 40 is arranged above the substrate W. The plurality of optical sensors 40 includes an irradiator (not shown) and a light receiver (not shown). The irradiator is configured to operate based on an operation signal from the controller Ctr and irradiate the surface of the substrate W being rotated by the rotation holder 10 with light. The light receiver is configured to receive light reflected from the surface of the substrate W (reflected light) and transmit the intensity of the reflected light (hereinafter referred to as “reflection intensity”) to the controller Ctr.

The optical sensor 40 may be, for example, a laser sensor, a photoelectric sensor, or a color sensor. When the optical sensor 40 is the laser sensor, the irradiator may use, for example, a red laser (wavelength: 655 nm) as laser light, a green laser (wavelength: 532 nm) as the laser light, a blue laser (wavelength: 405 nm) as the laser light or use another type of laser light.

The irradiator of the optical sensor 40 may irradiate the surface of the substrate W with light downward in a direction perpendicular to the surface of the substrate W. The irradiator of the optical sensor 40 may irradiate the surface of the substrate W with light through a light reflection member (e.g., a mirror), and the light receiver of the optical sensor 40 may receive the reflected light from the mirror. In these cases, the irradiator and the light receiver of the optical sensor 40 may be disposed in the same housing or may be physically separated.

The irradiator of the optical sensor 40 may irradiate the surface of the substrate W with light obliquely downward in an inclined direction with respect to the surface of the substrate W. In this case, the irradiator and the light receiver of the optical sensor 40 may be physically separated and may be disposed so that an irradiation position of light on the surface of the substrate W is located therebetween.

The plurality of optical sensors 40 may include three optical sensors 41 to 43, as illustrated in FIG. 2. The optical sensors 41 to 43 are configured to irradiate, with light, irradiation positions P1 to P3, respectively, which are set to overlap the surface of the substrate W held by the rotation holder 10, and receive light reflected from the irradiation positions P1 to P3, respectively. The irradiation positions P1 to P3 are fixed positions and do not change even when the substrate W rotates.

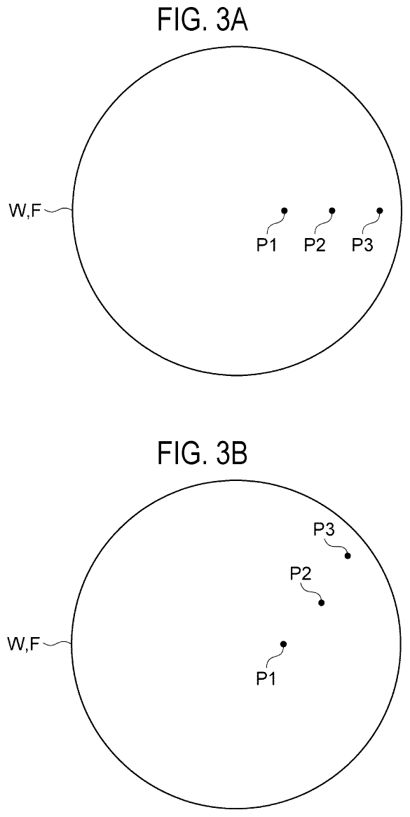

The irradiation positions P1 to P3 are set as different positions from each other, as illustrated in FIG. 2. That is, the irradiation positions P1 to P3 may be arranged from a center side toward a periphery side of the substrate W. Specifically, the irradiation position P2 may be located closer to the periphery side of the substrate W than the irradiation position P1, and the irradiation position P3 may be located closer to the periphery side of the substrate W than the irradiation position P2. The irradiation positions P1 to P3 may be arranged in a row in a radial direction of the substrate W, as illustrated in FIG. 3A. Alternatively, the irradiation positions P1 to P3 may not be arranged in the radial direction of the substrate W and may be arranged misaligned in a circumferential direction of the substrate W, as illustrated in FIG. 3B. That is, the irradiation positions P1 and P2 may not be on a straight line connecting the irradiation position P3 and the center of the substrate W, the irradiation positions P2 and P3 may not be on a straight line connecting the irradiation position P1 and the center of the substrate W, and the irradiation positions P1 and P3 may not be on a straight line connecting the irradiation position P2 and the center of the substrate W.

Intervals between the irradiation positions P1 to P3 may be substantially equal or different. When the radius of the substrate W is about 150 mm, the irradiation position P1 may be located about 50 mm from the center of the substrate W, the irradiation position P2 may be located about 100 mm from the center of the substrate W, and the irradiation position P3 may be located about 147 mm from the center of the substrate W.

### Details of Controller

As illustrated in FIG. 4, the controller Ctr has a reader M1, a storage M2, a processor M3, and an instructor M4 as functional modules. These functional modules are merely a division of functions of the controller Ctr into a plurality of modules for convenience and do not necessarily mean that hardware constituting the controller Ctr is divided into such modules. Each functional module is not limited to being implemented by the execution of a program and may be implemented by a dedicated electric circuit (e.g., logic circuit) or an integrated circuit (application specific integrated circuit (ASIC)) that integrates the dedicated electric circuit.

The reader M1 is configured to read a program from a computer-readable recording medium RM. The recording medium RM records a program for operating each part of the substrate processing system 1 including the liquid processing unit U. The recording medium RM may be, for example, a semiconductor memory, an optical recording disc, a magnetic recording disk, or a magneto-optical recording disk. In the following description, each part of the substrate processing system 1 may include the rotation holder 10, the supplies 20 and 30, and the optical sensor 40.

The storage M2 is configured to store various data. For example, the storage M2 may store a program read from the recording medium RM by the reader M1, setting data input by an operator via an external input device (not shown), etc. The storage M2 may store data of reflection intensity acquired by the optical sensor 40.

The storage M2 may store a model representing the relationship between the film thickness and reflection intensity of the film F. A method of generating the model is, for example, as follows. First, a test substrate W (sample substrate) is held by the rotation holder 10. Next, the controller Ctr controls the rotation holder 10 to rotate the test substrate W while adsorbing and holding a rear surface of the test substrate W. In this state, the controller Ctr controls the supplies 20 and 30 to sequentially supply the etching liquid L1 and the rinse liquid L2 to the surface of the test substrate W and etches the film F. Next, the film thickness of the etched film F is measured by a known film thickness measuring apparatus. In addition, the etched film F is irradiated with light using the optical sensor 40, and the reflected light is received by the optical sensor 40 to measure the reflection intensity of the reflected light. Thereafter, the above process is performed on a plurality of test substrates W while changing an etching time, and the reflection intensities for a plurality of different film thicknesses are obtained, thereby generating the model that represents the relationship between the film thickness and the reflection intensity of the film F.

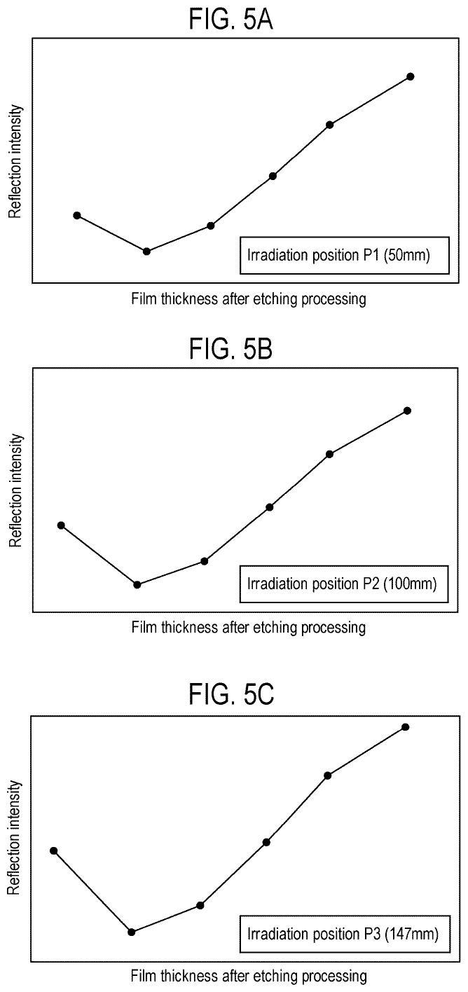

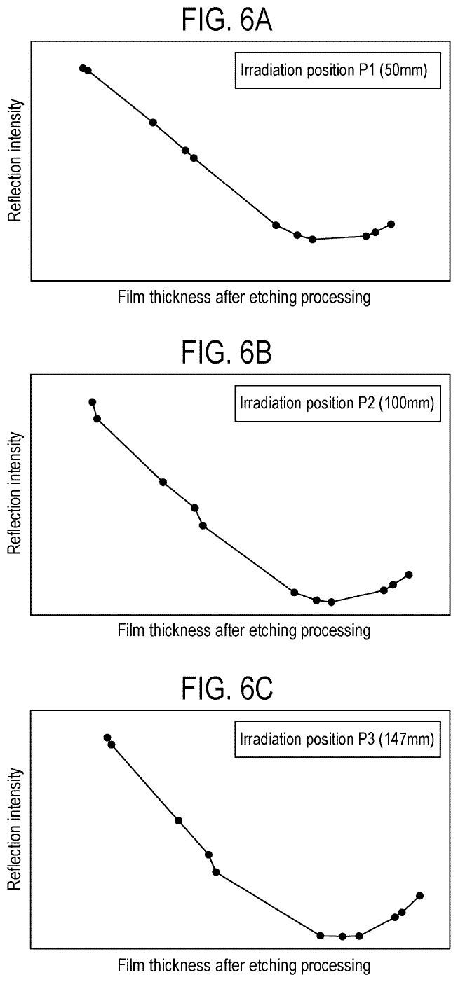

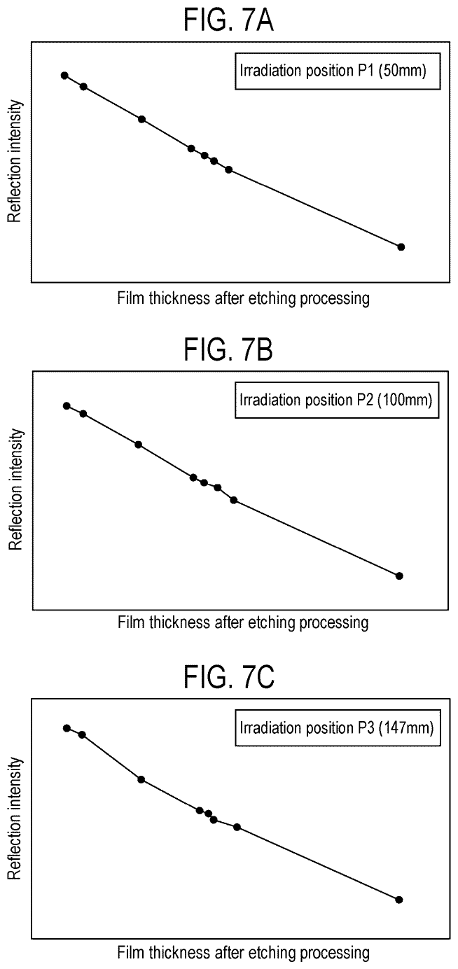

Here, examples of the model are illustrated in FIGS. 5A to 7C. FIGS. 5A to 5C are examples of models representing the relationship between film thickness and reflection intensity at respective positions of the irradiation position P1 (50 mm), the irradiation position P2 (100 mm), and the irradiation position P3 (147 mm) when the substrate W in which the film F is formed of titanium nitride is used. FIGS. 6A to 6C are examples of models representing the relationship between film thickness and reflection intensity at respective positions of the irradiation position P1 (50 mm), the irradiation position P2 (100 mm), and the irradiation position P3 (147 mm) when the substrate W in which the film F is formed of silicon nitride (SiN) is used. FIGS. 7A to 7C are examples of models representing the relationship between film thickness and reflection intensity at respective positions of the irradiation position P1 (50 mm), the irradiation position P2 (100 mm), and the irradiation position P3 (147 mm) when the substrate W in which the film F is formed of a thermal oxide (Th-Ox) film is used. The optical sensor 40 used in generating each of the models in FIGS. 5A to 7C was a laser sensor, and the wavelength of the laser light thereof was 655 nm.

The processor M3 is configured to process various data. The processor M3 may generate a signal for operating each part of the substrate processing system 1 based on, for example, various data stored in the storage M2.

The instructor M4 is configured to transmit the operation signal generated in the processor M3 to each portion of the substrate processing system 1.

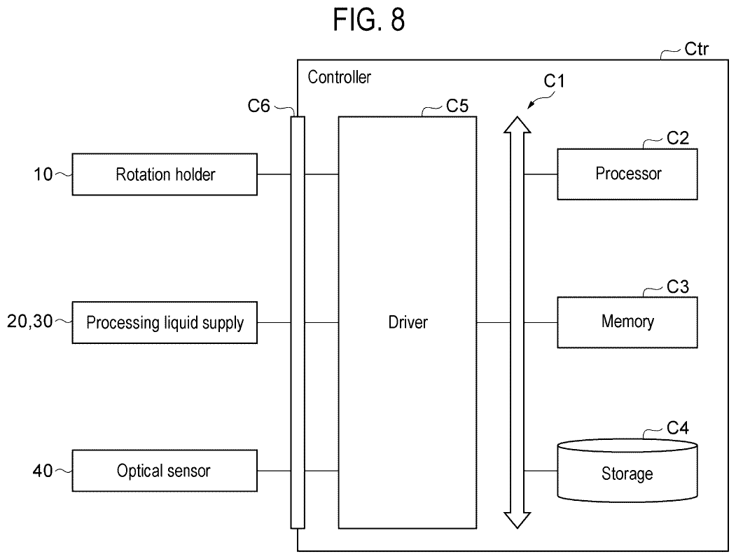

Hardware of the controller Ctr may be configured, for example, by one or more control computers. The controller Ctr may include a circuit C1 as a hardware configuration as illustrated in FIG. 8. The circuit C1 may be configured by electric circuitry. The circuit C1 may include, for example, a processor C2, a memory C3, a storage C4, a driver C5, and an input/output port C6.

The processor C2 may be configured to execute a program in cooperation with at least one of the memory C3 or the storage C4, and input and output of a signal through the input/output port C6, thereby implementing the above-mentioned functional modules. The memory C3 and the storage C4 may function as the storage M2. The driver C5 may be a circuit configured to drive each part of the substrate processing system 1. The input/output port C6 may be configured to relay input and output of signals between the driver C5 and each part of the substrate processing system 1.

The substrate processing system 1 may include one controller Ctr or may include a controller group (control portion) composed of a plurality of controllers Ctr. When the substrate processing system 1 includes the controller group, each of the above-mentioned functional modules may be implemented by one controller Ctr or may be implemented by a combination of two or more controllers Ctr. When the controller Ctr is composed of a plurality of computers (circuit C1), each of the above-mentioned functional modules may be implemented by one computer (circuit C1) or may be implemented by a combination of two or more computers (circuits C1). The controller Ctr may have a plurality of processors C2. In this case, each of the above-mentioned functional modules may be implemented by one processor C2 or may be implemented by a combination of two or more processors C2.

### Substrate Processing Method

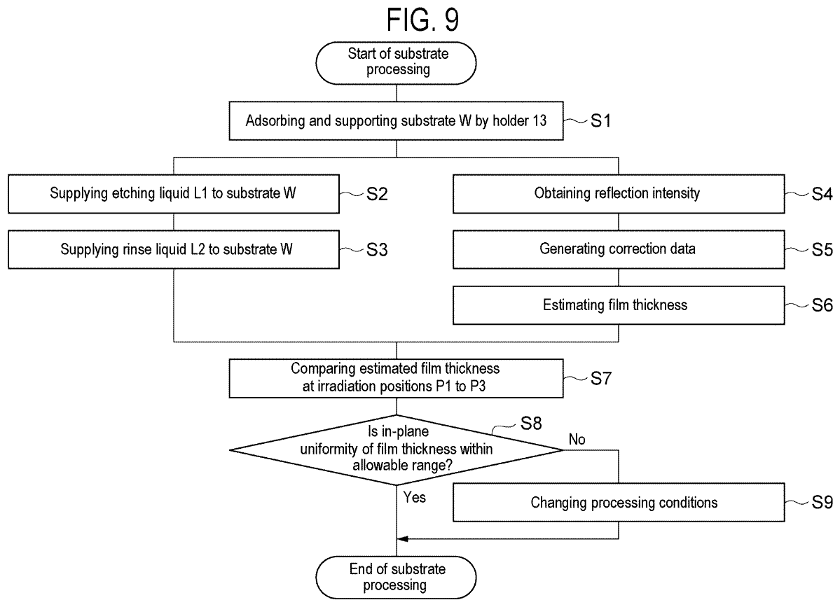

Next, a method of processing a substrate W using a processing liquid will be described with reference to FIGS. 9 to 11.

First, the carrier 7 is placed on the stage of the stage portion 4. At least one substrate W of the same type is accommodated in the carrier 7. Next, the controller Ctr controls the transfer arms A1 and A2 to take one substrate W out of the carrier 7 and transfer the substrate to one of the liquid processing units U. The substrate W transferred to the liquid processing unit U is adsorbed and held by the holder 13 (see step S1 in FIG. 9).

Next, the controller Ctr controls the rotation holder 10 to rotate the substrate W while adsorbing and holding the lower surface Wb of the substrate W by the holder 13. In this state, the controller Ctr controls the supply 20 to supply the etching liquid L1 from the nozzle 24 to the surface of the substrate W for a predetermined time (see step S2 in FIG. 9). In this case, the nozzle 24 and the arm 26 may perform a scan-in operation or a scan-out operation. The etching liquid L1 supplied to the surface of the substrate W expands over the entire surface of the substrate W due to the rotation of the substrate W and is shaken off outward from the periphery of the substrate W. Therefore, while the etching liquid L1 from the nozzle 24 continues to be supplied, a liquid film of the etching liquid L1 is formed on the surface of the substrate W. As a result, the film F is etched.

Next, the controller Ctr controls the rotation holder 10 to rotate the substrate W while the holder 13 adsorbs and holds the lower surface Wb of the substrate W. In this state, the controller Ctr controls the supply 30 to supply the rinse liquid L2 from the nozzle 34 to the surface of the substrate W for a predetermined time (see step S3 in FIG. 9). In this case, the nozzle 34 and the arm 36 may perform a scan-in or scan-out operation. The rinse liquid L2 supplied to the surface of the substrate W expands over the entire surface of the substrate W by the rotation of the substrate W and is shaken off outward from the periphery of the substrate W. Therefore, while the supply of the rinse liquid L2 from the nozzle 34 continues, a liquid film of the rinse liquid L2 is formed on the upper surface Wa of the substrate W. Thereby, the surface of the substrate W is cleaned.

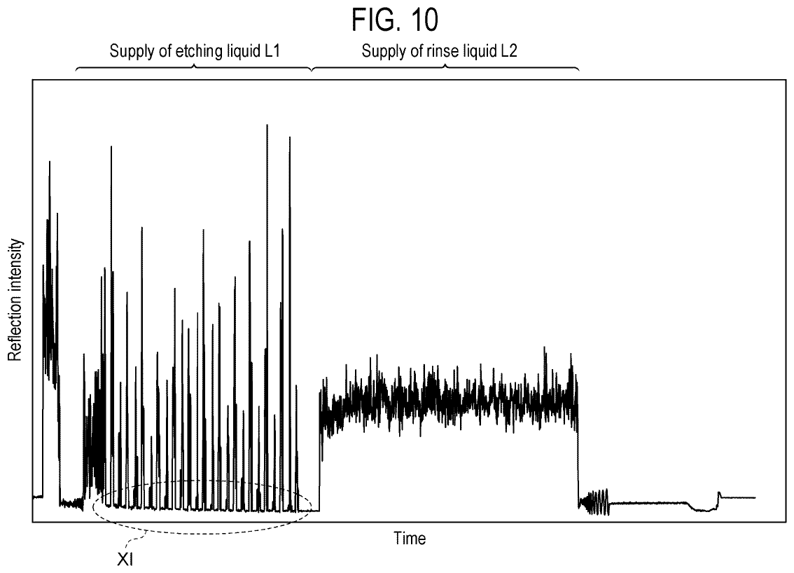

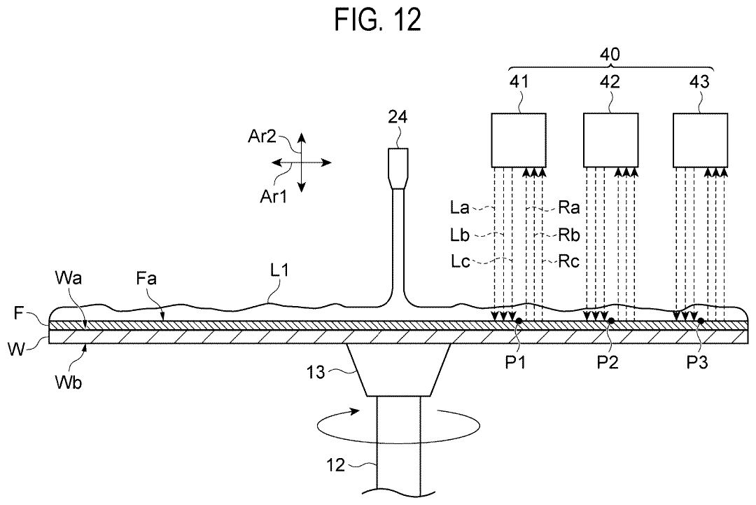

Meanwhile, when the etching liquid L1 and the rinse liquid L2 are being supplied to the surface of the substrate in steps S2 and S3, the controller Ctr controls the optical sensors 41 to 43. As a result, the optical sensors 41 to 43 irradiate the irradiation positions P1 to P3 with light and obtain intensity change data, which is data representing changes in reflection intensity, for the irradiation positions P1 to P3 (see step S4 in FIG. 9). FIG. 10 is a graph illustrating an example of intensity change data at the irradiation position P1. As illustrated in FIG. 10, while the etching liquid L1 is being supplied, reflection intensity is greatly disturbed as the nozzle 24 and the arm 26 perform the scan-in or scan-out operation. This is because, as the nozzle 24 and the arm 26 move, the nozzle 24 and the arm 26 overlap an optical path of the optical sensor 40, or the etching liquid L1 discharged from the nozzle 24 ripples on the surface of the substrate (see FIG. 12).

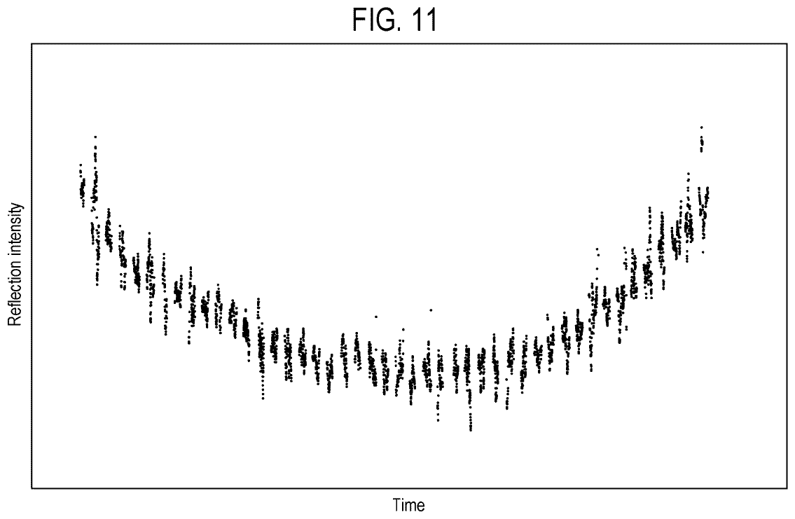

Therefore, the controller Ctr removes such a disturbance component generated by the influence of the nozzle 24 or the arm 26 using the intensity change data and generates correction data (see step S5 in FIG. 9). The correction data is generated for each of the intensity change data acquired for the irradiation positions P1 to P3. FIG. 11 is a graph illustrating correction data after removing a disturbance component from data during a supply period of the etching liquid L1 among the intensity change data exemplified in FIG. 10 and shows an enlarged view of a portion indicated by a dashed circle in FIG. 10.

The removal of the disturbance component from the intensity change data may be performed, for example, based on at least one of the position of the nozzle 24 or the arm 26 or the supply flow rate of the etching liquid L1 from the nozzle 24. More specifically, when the position of the nozzle 24 or the arm 26 approaches the irradiation positions P1 to P3 as the nozzle 24 or the arm 26 moves, an optical path of light from the optical sensor 40 overlaps the nozzle 24 or the arm 26, thereby greatly disturbing reflection intensity. Therefore, when the nozzle 24 or the arm 26 approaches within a predetermined range of the irradiation positions P1 to P3, intensity change data at that time may be excluded and the irradiation of light from the optical sensor 40 may be stopped. Alternatively, when the supply flow rate of the etching liquid L1 from the nozzle 24 increases, the etching liquid L1 is more likely to ripple on the surface of the substrate W. Therefore, when the supply flow rate becomes larger than a predetermined magnitude, the intensity change data at that time may be excluded and the irradiation of light from the optical sensor 40 may be stopped. Since processing conditions of the substrate W (such as the movement path of the arm 26 and the supply flow rate of the etching liquid L1) are determined in advance as a so-called recipe, a timing for removing the disturbance component from the intensity change data may be set based on the processing conditions.

Next, the controller Ctr estimates the thickness of the film F based on the correction data generated in step S5 (see step S6 in FIG. 9). Specifically, the thickness of the film F is estimated based on a model stored in the storage M2 and the reflection intensity of the correction data. By estimating the film thickness during an etching process of the film F, it is possible to monitor the progress of etching in real time. The process of step S6 is performed with respect to correction data for each of the irradiation positions P1 to P3. Therefore, the thickness of the film Fis estimated for each of the positions of the irradiation positions P1 to P3.

However, as exemplified in FIGS. 5A to 5C and 6A to 6C, some models may have extreme values. Therefore, there may be two thicknesses corresponding to a certain reflection intensity value, but since the thickness of the film decreases as etching progresses, which of the two thicknesses should be estimated can be determined depending on the progress of etching. As illustrated in FIG. 10, the processes of steps S4 to S6 may be performed from a time before the etching liquid L1 is supplied to the substrate W or may be performed continuously even after the supply of the rinse liquid L2 to the substrate W is completed.

After the supply of the rinse liquid L2 to the substrate W is completed and processing of the substrate W is completed, the controller Ctr compares the estimated film thickness at respective positions of the irradiation positions P1 to P3 (see step S7 in FIG. 9). Specifically, the difference between a maximum value and a minimum value of these estimated film thicknesses is calculated. Next, it is determined whether the difference is smaller than a predetermined threshold value (see step S8 in FIG. 9). If the difference is smaller than the predetermined threshold value, since a variation in the estimated film thicknesses at the respective positions of the irradiation positions P1 to P3 is small, it is determined that in-plane uniformity of the thickness of the film F after the etching process is within an allowable range (see “YES” in step S8 in FIG. 9). Therefore, after step S8, the processing of the substrate W is completed. Thereafter, a subsequent substrate W may be processed using the same liquid processing unit U under the same processing conditions.

On the other hand, if the difference is equal to or greater than the predetermined threshold, since the variation in the estimated film thicknesses at the respective positions of the irradiation positions P1 to P3 varies greatly, it is determined that the in-plane uniformity of the thickness of the film F after the etching process is outside the allowable range (see “NO” in step S8 of FIG. 9). In this case, there may be room for improving the processing conditions of the substrate W. Therefore, the controller Ctr changes the processing conditions of the subsequent substrate W (see step S9 of FIG. 9). Examples of the processing conditions that are changed include a discharge position of the etching liquid L1 discharged to the subsequent substrate W, the flow rate of the etching liquid L1 discharged to the subsequent substrate W, and the like. After step S9, the processing of the substrate W is completed, and the subsequent substrate W is processed in the liquid processing unit U under new processing conditions.

### Operation

According to the above example, since the intensity of reflected light changes depending on film thickness, film thickness that changes over time during the etching process can be estimated using the intensity change data. Moreover, since the correction data is generated by removing the disturbance component from the intensity change data, the film thickness can be estimated with high precision using the correction data even if the intensity change data is disturbed by the disturbance inducer (the nozzle 24 or arm 26). As a result, even in an environment with disturbance, it is possible to estimate, with high precision, the film thickness which changes over time during the etching process.

According to the above example, even when the etching liquid L1 is supplied to the surface of the substrate W while the arm 26 and the nozzle 24 are moved above the substrate W so that the etching liquid L1 expands substantially uniformly over the surface of the substrate W, the disturbance component generated by the arm 26 or the nozzle 24 is removed. Therefore, it is possible to estimate, with high precision, the film thickness that changes over time during the etching process while performing the etching process with greater precision.

According to the above example, when the location of the disturbance inducer (the nozzle 24 or the arm 26) approaches a predetermined range near the irradiation positions P1 to P3 or when the supply flow rate of the etching liquid L1 exceeds a predetermined magnitude, data of the intensity of the reflected light is excluded. Therefore, the correction data can be generated more accurately. Therefore, even in an environment with disturbance, it is possible estimate, with greater precision, the film thickness that changes over times during the etching process.

According to the above example, by acquiring the model in advance, the film thickness is immediately estimated from the intensity of the reflected light received by the optical sensor 40. Therefore, it is possible to estimate, with high precision and immediately, the film thickness which changes over time during the etching process.

According to the above example, the film thickness at different positions (irradiation positions P1 to P3) in a radial direction of the substrate W can be estimated. Therefore, it is possible to monitor the in-plane uniformity of the substrate W in the etching process based on a plurality of estimated film thicknesses.

According to the above example, processing conditions of the subsequent substrate W are changed based on the in-plane uniformity of the substrate W monitored based on the plurality of estimated film thicknesses. Therefore, the in-plane uniformity of the subsequent substrate W by the etching process is improved. In other words, the processing conditions of the substrate W are adjusted so that a processing result of the subsequent substrate W becomes better. Therefore, it is possible to process the substrate W more appropriately.

### Modifications

It is to be noted that the embodiment disclosed herein is exemplary in all respects and is not restrictive. The above-described embodiment may be omitted, replaced, and/or modified in various forms without departing from the scope and spirit of the appended claims.
(1) The etching liquid L1 may be supplied to the surface of the substrate W while the substrate W is not rotating.
(2) The optical sensor 40 may be configured to irradiate the same irradiation position with lights La to Lc of different wavelengths. In the example of FIG. 12, the optical sensor 41 may be configured to irradiate the irradiation position P1 with the lights La to Lc of three different wavelengths. The optical sensor 42 may be configured to irradiate the irradiation position P2 with the lights La to Lc of three different wavelengths. The optical sensor 43 may be configured to irradiate the irradiation position P3 with the lights La to Lc of three different wavelengths. The optical sensor 40 may independently receive reflected lights Ra to Rc of the lights La to Lc of different wavelengths via, for example, a filter. The controller Ctr may estimate film thicknesses at respective positions of the irradiation positions P1 to P3 based on respective intensities of the reflected lights Ra to Rc and models.

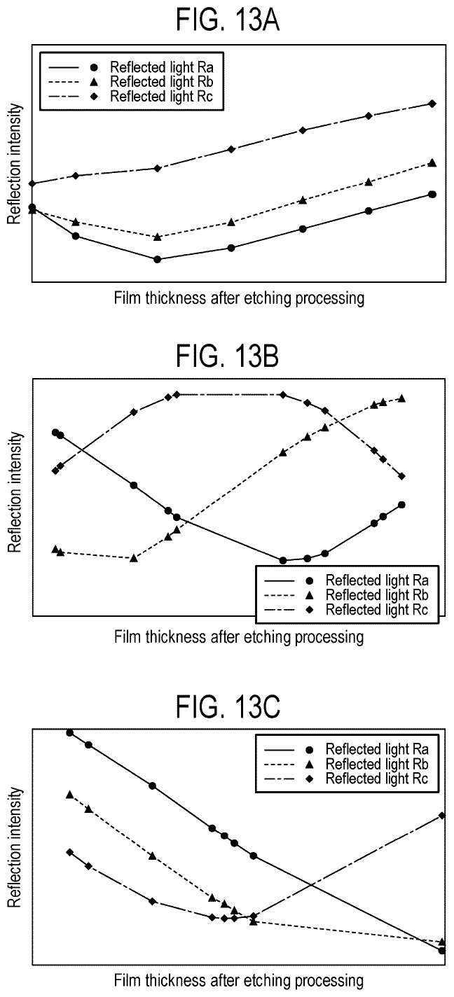

Here, the model may represent the relationship between the thickness of the film F and the intensity of each of the reflected lights Ra to Rc. A method of generating the model may be the same as the above-mentioned method. An example of the model is shown in FIGS. 13A to 13C. FIG. 13A is an example of a model representing the relationship between the film thickness at the irradiation position P1 (50 mm) and the intensities of the reflected lights Ra to Rc when the substrate W in which the film F is formed of titanium nitride is used. FIG. 13B is an example of a model representing the relationship between the film thickness at the irradiation position P1 (50 mm) and the intensities of the reflected light Ra to Rc when the substrate W in which the film F is formed of silicon nitride (SiN) is used. FIG. 13C is an example of a model representing the relationship between the film thickness at the irradiation position P1 (50 mm) and the intensities of the reflected light Ra to Rc when the substrate W in which the film Fis formed of a thermal oxide (Th-Ox) film is used. As illustrated in FIGS. 13A to 13C, when the wavelength of light is different, the relationship between the film thickness and the intensity of the reflected light is also different. Therefore, by estimating the film thickness based on intensities of respective reflected lights using lights of multiple wavelengths, it is possible to increase the accuracy of estimation of the film thickness.
(3) The controller Ctr may calculate etching results (e.g., etching amount, etching rate, etc.) in one etching process by obtaining the film thickness before and after etching of the substrate W based on the reflection intensity. The controller Ctr may determine whether the calculated etching results are within a predetermined allowable range. If the calculated etching results are not within the allowable range as a result of the determination, the processing of the substrate W may be inappropriate. Therefore, the controller Ctr may store, in the storage M2, the determination result indicting that the etching results are inappropriate. In this case, the controller Ctr may notice an alarm representing that the etching results are not within the allowable range through a notification portion (not shown) (e.g., an alarm may be displayed on a display, or an alarm sound or alarm guide may be generated from a speaker). Thereafter, the processing of the subsequent substrate W may be stopped, or the processing of the subsequent substrate W may be performed using a liquid processing unit U other than the liquid processing unit U in which the inappropriate processing of the substrate W may have been performed.

The controller Ctr may arrange the calculated etching results in chronological order and store the results in the storage M2 as a so-called log. The controller Ctr may predict a timing when the etching result is expected to fall outside the allowable range in the future based on log information accumulated over time. For example, when time series data of the etching results constituting the log gradually increases over time, the controller Ctr may predict a timing when the etching results in the future will exceed the allowable range by calculating an approximation line of the etching results. When the time series data of the etching results constituting the log gradually decreases over time, the controller Ctr may predict a timing when the etching results in the future will fall below the allowable range by calculating the approximation line of the etching results.
(4) The technique disclosed in this specification may be applied to measure a line width and shape of a pattern formed on the surface of the substrate. That is, the pattern may be irradiated with light from the optical sensor 40, and the line width and shape of the pattern may be measured based on the intensity of a reflected light of the irradiated light.

### OTHER EXAMPLES

Example 1. An example of a substrate processing apparatus includes a holder configured to hold a substrate having a film formed on a surface thereof, a supply configured to supply an etching liquid to the surface of the substrate, an optical sensor configured to irradiate an irradiation position set to overlap the surface of the substrate held by the holder with light of a predetermined wavelength and receive reflected light reflected from the irradiation position, and a controller. The controller is configured to execute a first process of supplying the etching liquid to the surface of the substrate held by the holder by controlling the supply, a second process of acquiring a change in intensity of the reflected light from the irradiation position, received by the optical sensor, while the etching liquid is being supplied to the surface of the substrate, a third process of generating correction data by removing a disturbance component generated by an influence of a disturbance inducer located above the substrate from intensity change data representing the change in the intensity of the reflected light acquired in the second process, and a fourth process of estimating a thickness of the film during an etching process based on the correction data. In this case, since the intensity of reflected light changes depending on the film thickness, the film thickness that changes over time during the etching process can be estimated using the intensity change data. Moreover, since the correction data is generated by removing the disturbance component from the intensity change data, the film thickness can be estimated with high precision using the correction data even if the intensity change data is disturbed by the disturbance inducer. As a result, even in an environment with disturbance, it is possible to estimate, with high precision, the film thickness which changes over time during the etching process.

Example 2. In the apparatus of Example 1, the supply may include a nozzle configured to discharge an etching liquid, and an arm configured to hold the nozzle and move the nozzle along the surface of the substrate above the substrate, and the disturbance inducer may be the arm or the nozzle. In this case, even when the etching liquid is supplied to the surface of the substrate while the arm and the nozzle are moved above the substrate so that the etching liquid expands substantially uniformly over the surface of the substrate, the disturbance component generated by the arm or the nozzle is removed. Therefore, it is possible to estimate, with high precision, the film thickness that changes over time during the etching process while performing the etching process with greater precision.

Example 3. In the apparatus of Example 2, the disturbance component may be generated by the arm or the nozzle overlapping an optical path of the optical sensor or generated by a liquid film on the surface of the substrate being disturbed by the etching liquid discharged from the nozzle.

Example 4. In the apparatus of any one of Example 1 to Example 3, the third process may include generating the correction data by removing the disturbance component from the intensity change data based on at least one of a location of the disturbance inducer or a supply flow rate of the etching liquid supplied by the supply. Normally, as the irradiation position of light by the optical sensor and the location of the disturbance inducer become closer, the optical path of light and the disturbance inducer are more likely to overlap, so the disturbance component tends to appear in the intensity change data. In addition, as the supply flow rate of the etching liquid increases, waves tend to occur in the liquid film of the etching liquid on the surface of the substrate, so the disturbance component tends to appear in the intensity change data. Thereby, when the location of the disturbance inducer approaches a predetermined range near the irradiation positions or when the supply flow rate of the etching liquid exceeds a predetermined magnitude, data of the intensity of the reflected light is excluded, thereby generating the correction data more accurately. Therefore, even in an environment with disturbance, it is possible estimate, with greater precision, the film thickness that changes over times during the etching process.

Example 5. In the apparatus of any one of Example 1 to Example 4, the fourth process may include estimating the thickness of the film on the substrate from intensity included in the correction data, based on a model representing a relationship between a thickness of a film formed on a surface of a sample substrate and intensity of reflected light obtained by the optical sensor by irradiating the surface of the sample substrate with light and receiving the reflected light of the light irradiated on the surface of the sample substrate. In this case, by acquiring the model in advance, the film thickness is immediately estimated from the intensity of the reflected light received by the optical sensor. Thereby, it is possible to estimate, with high precision and immediately, the film thickness which changes over time during the etching process.

Example 6. In the apparatus of any one of Example 1 to Example 5, the optical sensor may be configured to irradiate the irradiation position with the light and another light of predetermined wavelength and receive reflected lights of the light and the another light, and the second process may include acquiring the change in the intensity of the reflected light of the light and a change in intensity of the reflected light of the another light while the etching liquid is being supplied to the surface of the substrate. Here, if wavelengths of lights are different, the relationship between film thickness and intensity of reflected light is also different. Therefore, by estimating the film thickness based on intensities of respective reflected lights using lights of multiple wavelengths, it becomes possible to increase the accuracy of estimation of the film thickness.

Example 7. In the apparatus of any one of Example 1 to Example 6, the apparatus may further include another optical sensor configured to irradiate, with light, another irradiation position set as a position that overlaps the surface of the substrate held by the holder and is different from the irradiation position in a radial direction of the substrate and receive reflected light reflected from the another irradiation position, and the controller is configured to further execute a fifth process of acquiring a change in intensity of the reflected light reflected from the irradiation position received by the another optical sensor while the etching liquid is being supplied to the surface of the substrate, a sixth process of generating another correction data by removing the disturbance component generated by the influence of the disturbance inducer from intensity change data representing a change in the intensity of the reflected light acquired in the fifth process, and a seventh process of estimating the thickness of the film during the etching process based on the another correction data. In this case, the film thickness at different positions in the radial direction of the substrate can be estimated. Therefore, it is possible to monitor in-plane uniformity of the substrate in the etching process based on a plurality of estimated film thicknesses.

Example 8. In the apparatus of Example 7, the controller may be configured to further execute an eighth process of changing at least one of a discharge position of the etching liquid discharged by the supply onto a subsequent substrate or a flow rate of the etching liquid discharged by the supply onto the subsequent substrate, based on the thickness of the film estimated in the fourth process and the thickness of the film estimated in the seventh process. In this case, processing conditions of the subsequent substrate are changed based on the in-plane uniformity of the substrate monitored in Example 7. Therefore, the in-plane uniformity of the subsequent substrate by the etching process is improved. In other words, the processing conditions of the substrate are adjusted so that a processing result of the subsequent substrate becomes better. Therefore, it is possible to process the substrate more appropriately.

Example 9. In the apparatus of any one of Example 1 to Example 8, the holder may be configured to rotate the substrate while holding the substrate, and the first process may include supplying the etching liquid to the surface of the substrate which is being rotated by controlling the supply and the holder.

Example 10. A film thickness estimation method includes a first process of supplying, by a supply, an etching liquid to a surface of a substrate while the substrate having a film formed on the surface thereof is being held by a holder, a second process of irradiating, by an optical sensor, an irradiation position of the substrate held by the holder with light of a predetermined wavelength while the etching liquid is being supplied to the surface of the substrate and acquiring a change in intensity of reflected light reflected from the irradiation position received by the optical sensor, a third process of generating correction data by removing a disturbance component generated by an influence of a disturbance inducer located above the substrate from intensity change data representing the change in the intensity of the reflected light acquired in the second process, and a fourth process of estimating a thickness of the film during an etching process based on the correction data. In this case, the same operational effect as in Example 1 is obtained.

Example 11. In the method of Example 10, the supply may include a nozzle configured to discharge the etching liquid, and an arm configured to hold the nozzle and move the nozzle along the surface of the substrate above the substrate, and the disturbance inducer may be the arm or the nozzle. In this case, the same operational effect as in Example 2 is obtained.

Example 12. In the method of Example 11, the disturbance component may be generated by the arm or the nozzle overlapping an optical path of the optical sensor or generated by a liquid film on the surface of the substrate being disturbed by the etching liquid discharged from the nozzle.

Example 13. In the method of any one of Example 10 to Example 12, the third process may include generating the correction data by removing the disturbance component from the intensity change data based on at least one of a location of the disturbance inducer or a supply flow rate of the etching liquid supplied by the supply. In this case, the same operational effect as in Example 4 is obtained.

Example 14. In the method of any one of Example 10 to Example 13, the fourth process may include estimating the thickness of the film on the substrate from intensity included in the correction data, based on a model representing a relationship between a thickness of a film formed on a surface of a sample substrate and intensity of reflected light obtained by the optical sensor by irradiating the surface of the sample substrate with light and receiving the reflected light reflected from the surface of the sample substrate. In this case, the same operational effect as in Example 5 is obtained.

Example 15. In the method of any one of Example 10 to Example 14, the optical sensor may be configured to irradiate the irradiation position with the light and another light of another predetermined wavelength different from the predetermined wavelength of the light and receive the reflected light of the light and reflected light of the another light, and the second process may include acquiring the change in the intensity of the reflected light of the light and a change in intensity of the reflected light of the another light while the etching liquid is being supplied to the surface of the substrate. In this case, the same operational effect as in Example 6 is obtained.

Example 16. In the method of any one of Example 10 to Example 15, the method may further include a fifth process of irradiating, by another optical sensor, another irradiation position of the substrate held by the holder with another light of another predetermined wavelength while the etching liquid is being supplied to the surface of the substrate and acquiring a change in intensity of reflected light reflected from the another irradiation position received by the another optical sensor, wherein the another irradiation position is set as a position different from the irradiation position in a radial direction of the substrate, a sixth process of generating another correction data by removing the disturbance component generated by the influence of the disturbance inducer from intensity change data representing the change in the intensity of the reflected light acquired in the fifth process, and a seventh process of estimating the thickness of the film during the etching process based on the another correction data. In this case, the same operational effect as in Example 7 is obtained.

Example 17. In the method of Example 16, the method may further include an eighth process of changing at least one of a discharge position of the etching liquid discharged by the supply onto a subsequent substrate or a flow rate of the etching liquid discharged by the supply onto the subsequent substrate, based on the thickness of the film estimated in the fourth process and the thickness of the film estimated in the seventh process. In this case, the same operational effect as in Example 8 is obtained.

Example 18. In the method of any one of Example 10 to Example 17, the holder may be configured to rotate the substrate while holding the substrate, and the first process may include supplying the etching liquid to the surface of the substrate which is being rotated by controlling the supply and the holder.

### EXPLANATION OF REFERENCE NUMERALS

1: substrate processing system (substrate processing apparatus), 10: rotation holder (holder), 13: holder, 20: supply, 24: nozzle (disturbance inducer), 26: arm (disturbance inducer), 40: optical sensor, Ctr: controller, F: film, Fa: upper surface (surface), L1: etching liquid, P1 to P3: irradiation positions, U: liquid processing unit (substrate processing apparatus), W: substrate

1-18. (canceled)

19. A substrate processing apparatus, comprising:
a holder configured to hold a substrate having a film formed on a surface of the substrate;
a supply configured to supply an etching liquid to the surface of the substrate;
an optical sensor configured to irradiate an irradiation position set to overlap the surface of the substrate held by the holder with light of a predetermined wavelength and receive reflected light reflected from the irradiation position; and
a controller,
wherein the controller is configured to execute:
a first process of supplying the etching liquid to the surface of the substrate held by the holder by controlling the supply;
a second process of acquiring a change in intensity of the reflected light from the irradiation position, received by the optical sensor, while the etching liquid is being supplied to the surface of the substrate;
a third process of generating correction data by removing a disturbance component generated by an influence of a disturbance inducer located above the substrate from intensity change data representing the change in the intensity of the reflected light acquired in the second process; and
a fourth process of estimating a thickness of the film during an etching process based on the correction data.

20. The substrate processing apparatus of claim 19, wherein the supply includes:
a nozzle configured to discharge the etching liquid; and
an arm configured to hold the nozzle and move the nozzle along the surface of the substrate above the substrate, and
wherein the disturbance inducer is the arm or the nozzle.

21. The substrate processing apparatus of claim 20, wherein the disturbance component is generated by the arm or the nozzle overlapping an optical path of the optical sensor, or generated by a liquid film on the surface of the substrate being disturbed by the etching liquid discharged from the nozzle.

22. The substrate processing apparatus of claim 21, wherein the optical sensor is further configured to irradiate the irradiation position with the light and another light of another predetermined wavelength, and receive the reflected light of the light and reflected light of the another light, and
wherein the second process includes acquiring the change in the intensity of the reflected light of the light and a change in intensity of the reflected light of the another light while the etching liquid is being supplied to the surface of the substrate.

23. The substrate processing apparatus of claim 19, wherein the third process includes generating the correction data by removing the disturbance component from the intensity change data based on at least one of a location of the disturbance inducer or a supply flow rate of the etching liquid supplied by the supply.

24. The substrate processing apparatus of claim 19, wherein the fourth process includes estimating the thickness of the film on the substrate from intensity included in the correction data, based on a model representing a relationship between a thickness of a film formed on a surface of a sample substrate and intensity of reflected light obtained by the optical sensor by irradiating the surface of the sample substrate with light and receiving the reflected light reflected from the surface of the sample substrate.

25. The substrate processing apparatus of claim 19, wherein the optical sensor is further configured to irradiate the irradiation position with the light and another light of another predetermined wavelength, and receive the reflected light of the light and reflected light of the another light, and
wherein the second process includes acquiring the change in the intensity of the reflected light of the light and a change in intensity of the reflected light of the another light while the etching liquid is being supplied to the surface of the substrate.

26. The substrate processing apparatus of claim 19, further comprising another optical sensor configured to irradiate, with another light, another irradiation position set as a position that overlaps the surface of the substrate held by the holder and is different from the irradiation position in a radial direction of the substrate and receive reflected light reflected from the another irradiation position,
wherein the controller is configured to further execute:
a fifth process of acquiring a change in intensity of the reflected light reflected from the another irradiation position received by the another optical sensor while the etching liquid is being supplied to the surface of the substrate;
a sixth process of generating another correction data by removing the disturbance component generated by the influence of the disturbance inducer from intensity change data representing the change in the intensity of the reflected light acquired in the fifth process; and
a seventh process of estimating the thickness of the film during the etching process based on the another correction data.

27. The substrate processing apparatus of claim 26, wherein the controller is configured to further execute an eighth process of changing at least one of a discharge position of the etching liquid discharged by the supply onto a subsequent substrate or a flow rate of the etching liquid discharged by the supply onto the subsequent substrate, based on the thickness of the film estimated in the fourth process and the thickness of the film estimated in the seventh process.

28. The substrate processing apparatus of claim 19, wherein the holder is configured to rotate the substrate while holding the substrate, and
wherein the first process includes supplying the etching liquid to the surface of the substrate which is being rotated by controlling the supply and the holder.

29. A film thickness estimation method, comprising:
a first process of supplying, by a supply, an etching liquid to a surface of a substrate while the substrate having a film formed on the surface of the substrate is being held by a holder;
a second process of irradiating, by an optical sensor, an irradiation position of the substrate held by the holder with light of a predetermined wavelength while the etching liquid is being supplied to the surface of the substrate and acquiring a change in intensity of reflected light reflected from the irradiation position received by the optical sensor;
a third process of generating correction data by removing a disturbance component generated by an influence of a disturbance inducer located above the substrate from intensity change data representing the change in the intensity of the reflected light acquired in the second process; and
a fourth process of estimating a thickness of the film during an etching process based on the correction data.

30. The film thickness estimation method of claim 29, wherein the supply includes:
a nozzle configured to discharge the etching liquid; and
an arm configured to hold the nozzle and move the nozzle along the surface of the substrate above the substrate, and
wherein the disturbance inducer is the arm or the nozzle.

31. The film thickness estimation method of claim 30, wherein the disturbance component is generated by the arm or the nozzle overlapping an optical path of the optical sensor, or generated by a liquid film on the surface of the substrate being disturbed by the etching liquid discharged from the nozzle.

32. The film thickness estimation method of claim 31, wherein the optical sensor is configured to irradiate the irradiation position with the light and another light of another predetermined wavelength different from the predetermined wavelength of the light, and receive the reflected light of the light and reflected light of the another light, and
wherein the second process includes acquiring the change in the intensity of the reflected light of the light and a change in intensity of the reflected light of the another light while the etching liquid is being supplied to the surface of the substrate.

33. The film thickness estimation method of claim 29, wherein the third process includes generating the correction data by removing the disturbance component from the intensity change data based on at least one of a location of the disturbance inducer or a supply flow rate of the etching liquid supplied by the supply.

34. The film thickness estimation method of claim 29, wherein the fourth process includes estimating the thickness of the film on the substrate from intensity included in the correction data, based on a model representing a relationship between a thickness of a film formed on a surface of a sample substrate and intensity of reflected light obtained by the optical sensor by irradiating the surface of the sample substrate with light and receiving the reflected light reflected from the surface of the sample substrate.

35. The film thickness estimation method of claim 29, wherein the optical sensor is configured to irradiate the irradiation position with the light and another light of another predetermined wavelength different from the predetermined wavelength of the light, and receive the reflected light of the light and reflected light of the another light, and
wherein the second process includes acquiring the change in the intensity of the reflected light of the light and a change in intensity of the reflected light of the another light while the etching liquid is being supplied to the surface of the substrate.

36. The film thickness estimation method of claim 29, further comprising:
a fifth process of irradiating, by another optical sensor, another irradiation position of the substrate held by the holder with another light of another predetermined wavelength while the etching liquid is being supplied to the surface of the substrate and acquiring a change in intensity of reflected light reflected from the another irradiation position received by the another optical sensor, wherein the another irradiation position is set as a position different from the irradiation position in a radial direction of the substrate;
a sixth process of generating another correction data by removing the disturbance component generated by the influence of the disturbance inducer from intensity change data representing the change in the intensity of the reflected light acquired in the fifth process; and
a seventh process of estimating the thickness of the film during the etching process based on the another correction data.

37. The film thickness estimation method of claim 36, further comprising an eighth process of changing at least one of a discharge position of the etching liquid discharged by the supply onto a subsequent substrate or a flow rate of the etching liquid discharged by the supply onto the subsequent substrate, based on the thickness of the film estimated in the fourth process and the thickness of the film estimated in the seventh process.

38. The film thickness estimation method of claim 29, wherein the holder is configured to rotate the substrate while holding the substrate, and
wherein the first process includes supplying the etching liquid to the surface of the substrate which is being rotated by controlling the supply and the holder.
